(19) United States
(12) Patent Application Publication
(10) Pub. No.: US 2009/0229666 A1
(43) Pub. Date: Sep. 17, 2009

(54) SMOOTHING A METALLIC SUBSTRATE FOR A SOLAR CELL

(76) Inventors: Jason Stephan Corneille, San Jose, CA (US); Steven Thomas Croft, Menlo Park, CA (US); Mulugeta Zerfu Wudu, San Jose, CA (US); William James McColl, Palo Alto, CA (US)

Correspondence Address: Weaver Austin Villeneuve & Sampson LLP, P.O. BOX 70250, OAKLAND, CA, 94612-0250, US

(21) Appl. No.: 12/049,159

(22) Filed: Mar. 14, 2008

(51) Int. Cl. H01L 31/032; H01L 31/04; B05D 5/00

(52) U.S. Cl. 136/262; 427/532; 427/554; 136/252

(57) ABSTRACT

A method for smoothing the surface of a metallic substrate. The method includes providing a metallic substrate and smoothing a surface of the metallic substrate by irradiating the surface with a high-intensity energy source, such that the surface is smoothed to remove defects from the surface by creating an altered surface layer. The altered surface layer is configured to receive at least one layer in a fabrication process of an electronic device.

### TECHNICAL FIELD

Embodiments of the present invention relate generally to the field of photovoltaic technology.

### BACKGROUND

In the drive for renewal sources of energy, photovoltaic technology has assumed a preeminent position as a cheap renewable source of clean energy. In particular, solar cells based on the compound semiconductor copper indium gallium diselenide (CIGS) used as an absorber layer offer great promise for thin-film solar cells having high efficiency and low cost. In efforts to obtain thin-film solar cells based on CIGS with lower cost, technological development has pursued a goal of using substrates having a large areal footprint, on the order of 1 meter in width, and equal or greater length. Recently, manufacturing schemes employing in-line coating processes on substrates provided from roll sheet stock have been investigated to achieve this goal.

However, unlike the small form-factor substrates used in the past to fabricate laboratory demonstrations of thin-film solar cells, these new substrate materials present a number of engineering challenges. One such challenge is conditioning these new substrates to receive the layers deposited upon the substrates during the solar-cell fabrication process while maintaining: high yields for the process, a defect-free substrate that produces high performance, and high solar-cell efficiency, as a figure of merit.

### SUMMARY

Embodiments of the present invention include a method for smoothing the surface of a metallic substrate. In one embodiment, the method includes providing a metallic substrate and smoothing a surface of the metallic substrate by irradiating the surface with a high-intensity energy source, such that the surface is smoothed to remove defects from the surface by creating an altered surface layer. The altered surface layer is configured to receive at least one layer in a fabrication process of an electronic device.

### DESCRIPTION OF THE DRAWINGS

The accompanying drawings, which are incorporated in and form a part of this specification, illustrate embodiments of the invention and, together with the description, serve to explain the embodiments of the invention:

FIG. 1A is a cross-sectional elevation view of a layer structure of a solar cell, in accordance with an embodiment of the present invention.

FIG. 1B is a schematic diagram of a model circuit of a solar cell, electrically connected to a load, in accordance with an embodiment of the present invention.

FIG. 2A is a cross-sectional elevation view of a metallic substrate prior to deposition of layers in fabrication of a solar cell illustrating various types of defects at a surface of the metallic substrate having potentially deleterious effects on solar-cell efficiency, upon which embodiments of the present invention may be implemented.

FIG. 2B is an expanded view of a portion of the cross-sectional elevation view of FIG. 2A after depositing layers to fabricate a solar cell on the metallic substrate illustrating a portion of photocurrent being lost to a shunt defect associated with a defect at the surface of the metallic substrate, upon which embodiments of the present invention may be implemented.

FIG. 3A is a cross-sectional elevation view of a metallic substrate after irradiating a surface of the metallic substrate with a high-intensity energy source, in accordance with an embodiment of the present invention.

FIG. 3B is an expanded view of a portion of the cross-sectional elevation view of FIG. 3A after irradiating a surface of the metallic substrate with a high-intensity energy source and depositing layers to fabricate a solar cell, the layers disposed on an altered surface layer of the metallic substrate, in accordance with an embodiment of the present invention.

FIG. 4 is an elevation view of a roll-to-roll surface smoother for smoothing the surface of a substrate in roll form from a roll of material, in accordance with an embodiment of the present invention.

FIG. 5 is flow chart illustrating a method for smoothing the surface of a metallic substrate, in accordance with an embodiment of the present invention.

FIG. 6 is flow chart illustrating a method for fabricating a solar cell, in accordance with an embodiment of the present invention.

FIG. 7 is flow chart illustrating a method for roll-to-roll smoothing the surface of a substrate, in accordance with an embodiment of the present invention.

The drawings referred to in this description should not be understood as being drawn to scale except if specifically noted.

### DESCRIPTION OF EMBODIMENTS

Reference will now be made in detail to the various embodiments of the present invention. While the invention will be described in conjunction with the various embodiments, it will be understood that they are not intended to limit the invention to these embodiments. On the contrary, the invention is intended to cover alternatives, modifications and equivalents, which may be included within the spirit and scope of the invention as defined by the appended claims.

Furthermore, in the following description of embodiments of the present invention, numerous specific details are set forth in order to provide a thorough understanding of the present invention. However, it should be appreciated that embodiments of the present invention may be practiced without these specific details. In other instances, well known methods, procedures, and components have not been described in detail as not to unnecessarily obscure embodiments of the present invention.

### Physical Description of Embodiments of the Present Invention for a Solar Cell

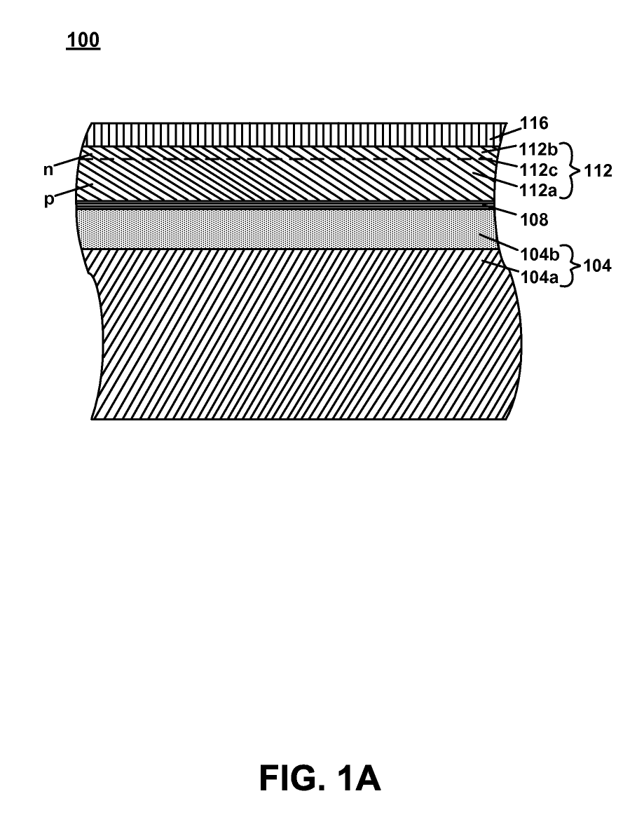

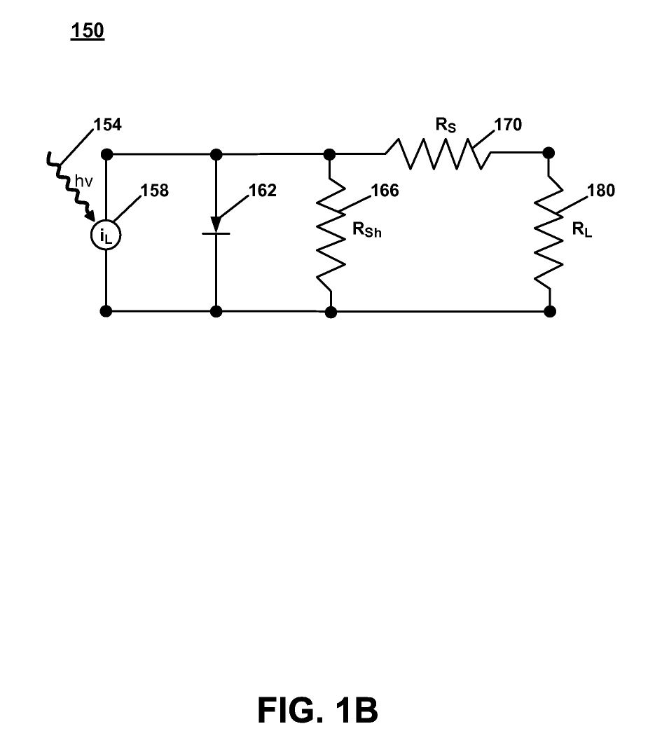

With reference to FIG. 1A, in accordance with an embodiment of the present invention, a cross-sectional elevation view of a layer structure of a solar cell 100 is shown. The solar cell 100 includes a metallic substrate 104. A surface of the metallic substrate 104 is smoothed by irradiating the surface of the metallic substrate 104 with a high-intensity energy source, wherein the surface is smoothed to remove defects from the surface by creating an altered surface layer 104b of the metallic substrate 104 on a supporting portion 104a of the metallic substrate 104. In accordance with the embodiment of the present invention, an absorber layer 112 is disposed on the altered surface layer 104b; the absorber layer 112 may include a layer of the material copper indium gallium diselenide (CIGS) having the chemical formula Cu(In₁₋ₓGaₓ)Se₂, where x may be a decimal less than one but greater than zero that determines the relative amounts of the constituents, indium, In, and gallium, Ga.

As shown, the absorber layer 112 includes a p-type portion 112a and an n-type portion 112b. As a result, a pn homojunction 112c is produced in the absorber layer 112 that seives to separate charge carriers that are created by light incident on the absorber layer 112. To facilitate the efficient conversion of light energy to charge carriers in the absorber layer 112, the composition of the p-type portion 112a of the absorber layer 112 may vary with depth to produce a graded band gap of the absorber layer 112. Alternatively, the absorber layer 112 may include only a p-type CIGS material layer and a pn heterojunction may be produced between the absorber layer 112 and an n-type layer, such as cadmium sulfide, CdS, zinc sulfide, ZnS, or indium sulfide, InS, disposed on its top surface in place of the n-type portion 112b shown in FIG. 1A. However, embodiments of the present invention are not limited to pn junctions fabricated in the manner described above, but rather a generic pn junction produced either as a homojunction in a single semiconductor material, or alternatively as a heterojunction between two different semiconductor materials, is within the spirit and scope of embodiments of the present invention.

In accordance with an embodiment of the present invention, on the surface of the n-type portion 112b of the absorber layer 112, a transparent electrically conductive oxide (TCO) layer 116 is disposed, for example, to provide a means for collection of current flow from the absorber layer 112 for conduction to an external load. The TCO layer 116 may include zinc oxide, ZnO, or alternatively a doped conductive oxide, such as aluminum zinc oxide, AlₓZn₁₋ₓO_{y}, and indium tin oxide, InₓSn₁₋ₓO_{y}, where the subscripts x and y indicate that the relative amount of the constituents may be varied. These TCO layer materials may be sputtered directly from an oxide target, or alternatively the TCO layer may be reactively sputtered in an oxygen atmosphere from a metallic target, such as zinc, Zn, Al—Zn alloy, or In—Sn alloy targets. For example, the zinc oxide may be deposited on the absorber layer 112 by sputtering from a zinc-oxide-containing target, alternatively, the zinc oxide may be deposited from a zinc-containing target in a reactive oxygen atmosphere in a reactive-sputtering process. The reactive-sputtering process may provide a means for doping the absorber layer 112 with an n-type dopant, such as zinc, Zn, or indium, In, to create a thin n-type portion 112b, if the partial pressure of oxygen is initially reduced during the initial stages of sputtering a metallic target, such as zinc, Zn, or indium, In, and the layer structure of the solar cell 100 is subsequently annealed to allow interdiffusion of the zinc, Zn, or indium, In, with the CIGS material of the absorber layer 112. Alternatively, sputtering a compound target, such as zinc sulfide, ZnS, indium sulfide, InS, or cadmium sulfide, CdS, may also be used to provide the n-type layer, as described above, on the p-type portion 112a of the absorber layer 112.

With further reference to FIG. 1A, in accordance with the embodiment of the present invention, a conductive backing layer 108 may be disposed between the absorber layer 112 and the altered surface layer 104b of the metallic substrate 104 to provide a diffusion barrier between the absorber layer 112 and the metallic substrate 104. The conductive backing layer 108 may include molybdenum, Mo, or other suitable metallic layer having a low propensity for interdiffusion with the absorber layer 112 composed of CIGS material, as well as a low diffusion coefficient for constituents of the substrate. Moreover, the conductive backing layer 108 may provide other functions in addition to, or independent of, the diffusion-barrier function, for example, a light-reflecting function, for example, as a light-reflecting layer, to enhance the efficiency of the solar cell, as well as other functions. The embodiments recited above for the conductive backing layer 108 should not be construed as limiting the function of the conductive backing layer 108 to only those recited, as other functions of the conductive backing layer 108 are within the spirit and scope of embodiments of the present invention, as well.

With reference now to FIG. 1B, in accordance with an embodiment of the present invention, a schematic diagram of a model circuit 150 of a solar cell that is electrically connected to a load is shown. The model circuit 150 of the solar cell includes a current source 158 that generates a photocurrent, i_{L}. The photocurrent, i_{L}, is produced when a plurality of incident photons, light particles, of which one example photon 154 with energy, hv, is shown, produce electron-hole pairs in the absorber layer 112 and these electron-hole pairs are separated by the pn homojunction 112c, or in the alternative, by a pn heterojunction as described above. It should be appreciated that the energy, hv, of each incident photon of the plurality of photons should exceed the band-gap energy, E_{g}, that separates the valence band from the conduction band of the absorber layer 112 to produce such electron-hole pairs, which result in the photocurrent, i_{L}.

The model circuit 150 of the solar cell further includes a diode 162, which corresponds to recombination currents, primarily at the pn homojunction 112c, that are shunted away from the connected load. In addition, the model circuit 150 of the solar cell includes two parasitic resistances corresponding to a shunt resistor 166 with shunt resistance, Rₛₕ, and to a series resistor 170 with series resistance, Rₛ. The solar cell may be connected to a load represented by a load resistor 180 with load resistance, R_{L}. Thus, the circuit elements of the solar cell include the current source 158, the diode 162 and the shunt resistor 166 connected across the current source 158, and the series resistor 170 connected in series with the load resistor 180 across the current source 158, as shown. As the shunt resistor 166, like the diode 162, are connected across the current source 158, these two circuit elements are associated with internal currents within the solar cell shunted away from useful application to the load. As the series resistor 170 connected in series with the load resistor 180 are connected across the current source 158, the series resistor 170 is associated with internal resistance of the solar cell that limits the current flow to the load.

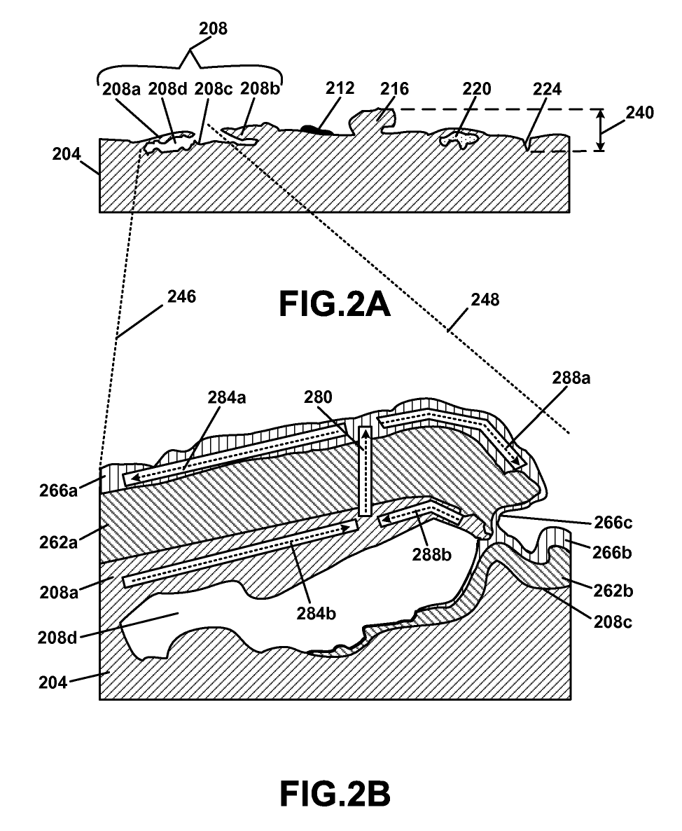

With further reference to FIG. 1B, it should be recognized that the shunt resistance may be associated with surface leakage currents that follow paths at free surfaces that cross the pn homojunction 112c; free surfaces are usually found at the edges of the solar cell along the side walls of the device that define its lateral dimensions; such free surfaces may also be found at discontinuities in the absorber layer 112 that extend past the pn homojunction 112c. The shunt resistance may also be associated with shunt defects which may be present that shunt current away from the load, as will subsequently be described in FIG. 2B. A small value of the shunt resistance, Rₛₕ, is undesirable as it lowers the open circuit voltage, V_{OC}, of the solar cell, which directly affects the efficiency of the solar cell. Moreover, it should also be recognized that the series resistance, Rₛ, is associated with: the contact resistance between the p-type portion 112a and the conductive backing layer 108, the bulk resistance of the p-type portion 112a, the bulk resistance of the n-type portion 112b, the contact resistance between the n-type portion 112b and TCO layer 116, and other components, such as conductive leads, and connections in series with the load. A large value of the series resistance, Rₛ, is undesirable as it lowers the short circuit current, I_{SC}, of the solar cell, which also directly affects the efficiency of the solar cell.

With reference now to FIG. 2A, a cross-sectional elevation view of an example metallic substrate 204 prior to deposition of layers in fabrication of a solar cell is shown that illustrates various types of defects at a surface of example metallic substrate 204 having potentially deleterious effects on solar-cell efficiency. In an embodiment of the present invention, example metallic substrate 204 has numerous defect types on its surface in the as-received state, which should be removed prior to deposition of layers in fabrication of the solar cell. Examples of the defect types at a surface of example metallic substrate 204 include, without limitation: pit 208, carbonaceous residue 212, protrusion 216, inclusion 220, and rolling groove 224. For example, pit 208 may include a left over-hanging portion 208a and a right over-hanging portion 208b, which may result from metallic flakes and protrusions being rolled onto the surface of example metallic substrate 204 during a rolling operation for reduction from billet stock down to rolled sheet stock. Pit 208 may further include a recessed portion 208c, which forms a bottom to pit 208, and a cavity portion 208d enveloped by the left and right over-hanging portions 208a and 208b, and recessed portion 208c. Carbonaceous residue 212 may originate from oil used to lubricate the roll bearings, or adventitious sources of contamination of the rolled sheet, during the rolling operation. Protrusion 216 may be generated by material extruded from the interior of the billet during the rolling operation. Inclusion 220 may be generated by surface oxides rolled under the surface of example metallic substrate 204 during the rolling operation. These oxides may originate from the oxidized layers, so called “scale,” a metallurgical term of art, that are natively present on the surface of billets, or may originate from foreign oxide particles such as alumina, silicates and alumina silicates that have an adventitious origin, which, during the rolling operation, are rolled under the surface of billets, which are used to produce the rolled sheet stock of example metallic substrate 204. Rolling groove 224 may be generated by direct interaction of the surface of the billet with the surface of the roll during the rolling operation in reducing the billet down to rolled sheet stock.

With reference now to FIG. 2B, an expanded view of a portion of the cross-sectional elevation view of FIG. 2A is shown as indicated by lines of projection 246 and 248. FIG. 2B illustrates a shunt portion 288a of photocurrent 280 being lost through a shunt defect associated with a defect, pit 208, at the surface of example metallic substrate 204 after layers have been deposited on example metallic substrate 204 to fabricate a solar cell. To simplify the discussion, FIG. 2B shows the solar cell structure more generically without a conductive backing layer, as may be the case, for example, in an embodiment of the present invention. A discontinuous absorber layer is shown in two portions: portion 262a disposed on the left over-hanging portion 208a of pit 208; and, portion 262b disposed on the recessed portion 208c of pit 208, which forms the bottom of the pit. The cavity portion 208d of the pit 208 is shown partially filled with material from the deposited layers of the solar cell structure. On portions 262a and 262b of the discontinuous absorber layer are disposed, respectively, three portions of an anomalous TCO layer: portion 266a disposed on portion 262a over the left of pit 208; portion 266b disposed on portion 262b at the bottom, recessed portion 208c, of pit 208; and, portion 266c disposed on a side-wall of portion 262a of the discontinuous absorber layer located at a discontinuity associated with the pit. The shunt defect is composed of a complex of the following structures: portion 266c of the anomalous TCO layer that bridges between the portion 266a and the top of portion 266b that makes electrical contact with the portion of the substrate shown as the bottom of the left over-hanging portion 208a of pit 208. As shown, the shunt defect provides a low-resistance current path between the example metallic substrate 204 and portion 266a of the anomalous TCO layer.

With further reference to FIG. 2B, a representative portion of the photocurrent 280 generated in the portion 262a of the discontinuous absorber layer is shown passing from the left over-hanging portion 208a of the pit to the portion 266a of the anomalous TCO layer. The photocurrent 280 divides into two separate portions: a load portion 284a, which passes to the left through the portion 266a of the anomalous TCO layer; and the shunt portion 288a, which passes to the right through the portion 266a of the anomalous TCO layer. The load portion 284a of the photocurrent 280 corresponds to a current flowing in circuit loop containing the load resistor 180 with load resistance, R_{L}, of FIG. 1B, described above, and completes the circuit through return load current 284b, which passes to the right through a portion of the example metallic substrate 204 shown as the left over-hanging portion 208a of pit 208. The shunt portion 288a of the photocurrent 280 corresponds to a current flowing in a circuit loop containing the shunt resistor 166 with shunt resistance, Rₛₕ, of FIG. 1B, and completes the circuit through return shunt current 288b, which passes to the left from the shunt defect found at the discontinuity in portion 262a of the discontinuous absorber Layer adjacent to entrance to the cavity portion 208d of the pit 208. Such shunt defects short circuit current that would otherwise pass to the load, which leads to loss of solar cell efficiency, and generate hot spots that can eventually lead to catastrophic shorts that break down the pn junction of the solar cell. Therefore, it is desirable to have some means for eliminating various types of defects at the surface of example metallic substrate 204 prior to deposition of layers in the fabrication of the solar cell.

Notwithstanding the problems attending the use of metallic substrates, such as example metallic substrate 204, it should be recognized that it is desirable to use such rolled sheet stock because of its low cost. However, removal of the defects at the surface of example metallic substrate 204 should be provided to preclude the costs attending yield losses of solar-cell production associated with these defects. Low-cost, rolled sheet stock suitable for use as example metallic substrate 204 may include stainless steel, aluminum, titanium, alloys of aluminum or titanium, any metallic foil, or even a metallized non-metallic substrate. Examples of aluminum and titanium alloys include aluminum-silicon alloy and titanium-aluminum alloy, respectively; an example of a metallized non-metallic substrate is a flexible, non-conductive substrate, such as a polymer substrate, with a sputtered metallic layer; and an example of a stainless steel is 430-alloy stainless steel. The defective surface region may include a peak-to-valley roughness 240 of about 5 μm, as shown in FIG. 2A. Therefore, in accordance with an embodiment of the present invention, it is desirable to have some means for treating example metallic substrate 204 to remove defects up to about 5 μm below the surface of example metallic substrate 204.

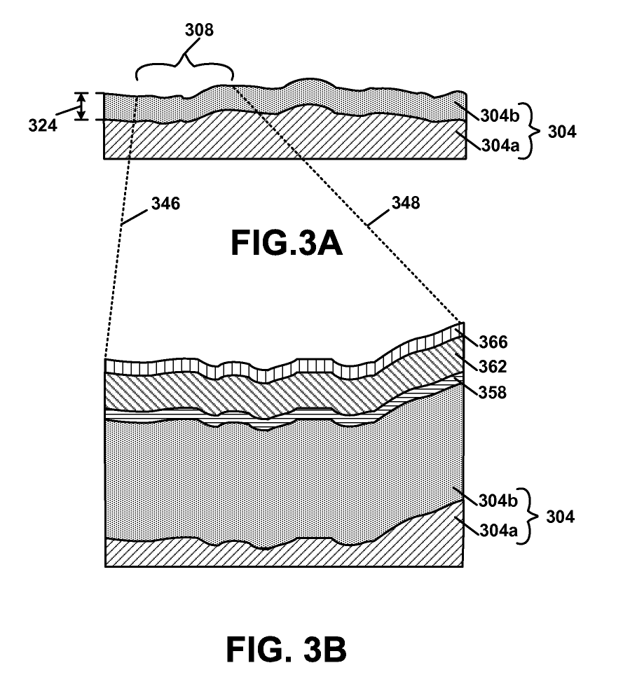

With reference now to FIG. 3A, in accordance with an embodiment of the present invention, a cross-sectional elevation view of a metallic substrate 304 after irradiating a surface of the metallic substrate 304 with a high-intensity energy source is shown. The metallic substrate 304 includes a supporting portion 304a and an altered surface layer 304b. The surface of the metallic substrate 304 is smoothed by irradiating the surface of the metallic substrate 304 with a high-intensity energy source, in which the surface is smoothed to remove defects from the surface by creating the altered surface layer 304b of the metallic substrate 304 on the supporting portion 304a of the metallic substrate 304. In one embodiment, the altered surface layer 304b has a thickness 324 of less than about 5 μm; alternatively, the altered surface layer 304b may be less than about 25 μm. Smoothing may be accomplished with a single pass of irradiation from the high-intensity energy source over the surface of the metallic substrate, or alternatively with a plurality of passes of irradiation from the high-intensity energy source over the surface of the metallic substrate. For example, two passes of irradiation from the high-intensity energy source may be used: a first, to remove inclusions from the surface, for example, by vaporization of the inclusions; a second, to further smooth the surface, for example, by reflowing vestigial craters at the location of inclusions vaporized in the first pass. Within the spirit and scope of embodiments of the present invention, additional passes beyond two may even be used with increasing improvement of the surface topography, although the accrued improvements may come with diminished returns.

After the metallic substrate 304 is smoothed, in accordance with an embodiment of the present invention, the metallic substrate 304 is suitable for further fabrication of an electronic device including, for example, a solar cell. An absorber layer 362 of the solar cell may be disposed on the altered surface layer 304b, as shown in FIG. 3B; the absorber layer 362 may include a layer of CIGS material. The smoothing may include a laser smoothing, wherein the laser smoothing further includes a process selected from a group including a laser ablation process, a laser melting-resolidification process, and a laser-induced, surface-alloying process. Similarly, the high-intensity energy source may include a laser selected from a group including a Q-switched laser, a Q-switched neodymium-doped, yttrium-aluminum-garnet (Nd:YAG) laser, a Q-switched fiber laser, a Q-switched disc laser, a Q-switched slab laser, a carbon-dioxide laser, a pulsed laser, a continuous-wave laser, and a diode laser. As described above in embodiments of the present invention, lasers have been identified as one type of high-intensity energy source, but this does not preclude other high-intensity energy sources outside of lasers that are within the spirit and scope of embodiments of the present invention. In addition, prior to irradiating the surface of the metallic substrate 304 with the high-intensity energy source, a surface-treatment layer may be deposited on the metallic substrate 304. The deposition process for depositing the surface-treatment layer may be selected from a group including physical vapor deposition (PVD), chemical vapor deposition (CVD), sol-gel deposition, sputtering, sputtering in a reactive atmosphere, cladding, laser cladding, electroplating, and electroless plating.

In accordance with an embodiment of the present invention, a Q-switched Nd:YAG laser may be used having a peak intensity of about 2 MW during a Q-switched pulse duration of about 40 ns; otherwise, in non-Q-switched, continuous mode operation, the Nd:YAG laser may an average power of 50 W. The laser beam delivered at the sample is homogenized by passing it through a beam homogenizer including an optical fiber having a square cross-section and a stepped index of refraction along its length to produce a large square spot of uniform intensity at the metallic substrate with a dimension of about 1.5 mm by 1.5 mm. In one embodiment of the present invention, the spot may be rastered across the surface of the sample in a raster pattern with a speed of about 4 m/s using a laser galvanometer scanner to produce an overall rate of laser smoothing of about 100 cm²/s.

With further reference to FIG. 3A, in accordance with the embodiment of the present invention, a portion 308 of the metallic substrate 304 corresponding to the pit 208 of FIG. 2A is shown after irradiating the surface of the metallic substrate 304 with a high-intensity energy source, such as a laser. The altered surface layer 304b of the metallic substrate 304 fills in the cavity portion 208d of the pit 208 leaving a gently undulating surface topography suitable for further fabrication of an electronic device, such as a solar cell. The other defects: the carbonaceous residue 212, the protrusion 216, the inclusion 220, and the rolling groove 224, have been removed from the surface of the metallic substrate 304 having either been ablated from the surface or incorporated into the altered surface layer 304b as alloying constituents, for example, the inclusion 220. The roughness of the surface after irradiating the metallic substrate 304 with a laser is substantially less than the peak-to-valley roughness 240, given by distance between the top of the protrusion 216 and the bottom of the rolling groove 224 shown in FIG. 2A, before irradiating the metallic substrate 304 with a laser.

With reference now to FIG. 3B, an expanded view of a portion of the cross-sectional elevation view of FIG. 3A is shown as indicated by lines of projection 346 and 348. In accordance with an embodiment of the present invention, a cross-sectional elevation view of a layer structure of a solar cell is shown as it would appear after irradiating the surface of the metallic substrate 304 with a high-intensity energy source, such as a laser, and depositing layers to fabricate the solar cell with the layers disposed on the altered surface layer 304b of the metallic substrate 304. The solar cell includes the metallic substrate 304 with the surface of the metallic substrate 304 smoothed by irradiating the surface with a high-intensity energy source, so that the surface is smoothed to remove defects from the surface by creating the altered surface layer 304b and the absorber layer 362 disposed on the altered surface layer 304b of the metallic substrate 304. The absorber layer 362 of the solar cell may include CIGS. A conductive backing layer 358 may be disposed between the absorber layer 362 and the altered surface layer 304b of the metallic substrate 304. On the surface of the absorber layer 362, a TCO layer 366 is disposed. As shown in the expanded view of FIG. 3B, the location corresponding to the cavity portion 208d of the pit 208 has a gently undulating surface topography. Therefore, the shunt defect associated with the defect, pit 208, shown in FIG. 2A, is absent, as well as other shunt defects, so that the number of shunt defects and density of shunt defects is reduced. In addition, the altered surface layer 304b has a thickness of less than about 5 μM sufficient to remove defects within 5 μm of the top of the original surface of the metallic substrate 304; alternatively, the altered surface layer 304b may have a thickness of less than about 25 μm depending on the power delivered to the surface of the metallic substrate 304 by the high-intensity energy source. Moreover, after smoothing the surface of the metallic substrate 304, the altered surface layer 304b has a gently undulating topography. The smoothing may include a laser smoothing which may also include a process selected from a group including a laser ablation process, a laser melting-resolidification process, and a laser-induced, surface-alloying process. In addition, the high-intensity energy source may include a laser selected from a group including a Q-switched laser, a Q-switched Nd:YAG laser, a Q-switched fiber laser, a Q-switched disc laser, a Q-switched slab laser, carbon-dioxide laser, a pulsed laser, a continuous-wave laser, and a diode laser.

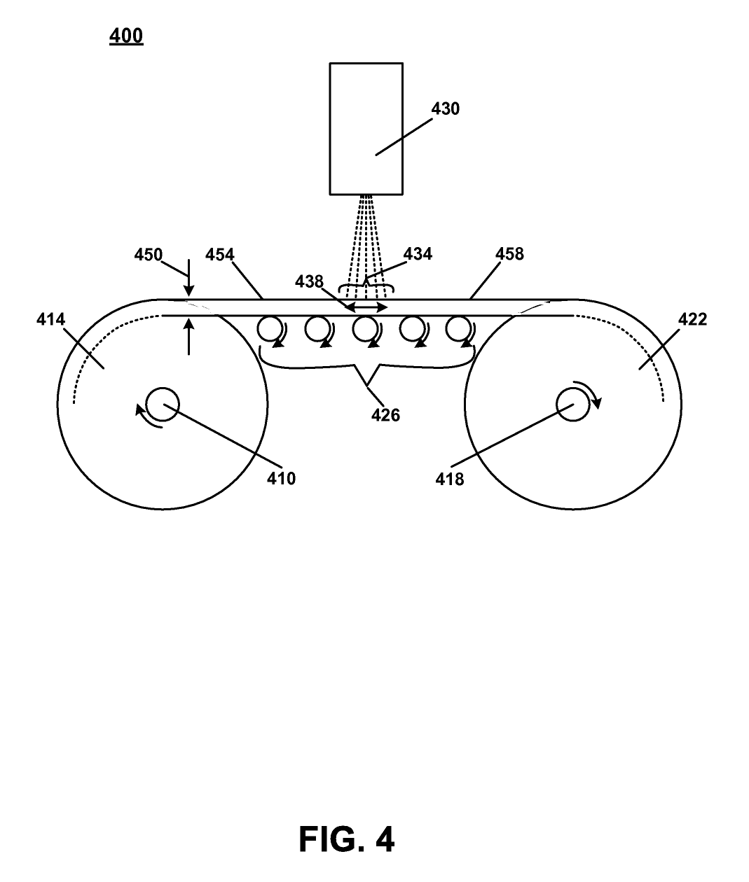

With reference now to FIG. 4, in accordance with an embodiment of the present invention, an elevation view of a roll-to-roll surface smoother 400 for smoothing the surface of substrate in roll form is shown. The substrate is provided to roll-to-roll surface smoother 400 in roll form from a roll of material 414. The roll-to-roll surface smoother 400 includes an unwinding spool 410 upon which the roll of material 414 including the substrate in roll form is mounted. As shown, a portion of the roll of material 414 is unwound and passes over a series of idler rollers 426, shown as five small circles in the center of FIG. 4, which provide a roller-platform upon which the unwound portion of the roll of material 414 may be transported. The unwound portion of the roll of material 414 passes to the right and is taken up on a take-up spool 418 upon which it is rewound as a smoothed roll of material 422 after the substrate has been smoothed. The arrows adjacent to the idler rollers 426, the unwinding spool 410, and the take-up spool 418 indicate that these are rotating components of the roll-to-roll surface smoother 400; the idler rollers 426, the unwinding spool 410, and the take-up spool 418 are shown rotating in clockwise direction, as indicated by the arrow-heads on the respective arrows adjacent to these components, to transport the unwound portion of the roll of material 414 from the unwinding spool 410 on the left to the take-up spool 418 on the right.

With further reference to FIG. 4, in accordance with an embodiment of the present invention, the roll of material 414 provides the substrate as a sheet having a width (not shown), as great as about 1 m, and a thickness 450, as great as about 125 μm. As provided the untreated surface 454 of the roll of material 414 passes under a surface treatment station on the way to the take-up spool 418. The surface treatment station includes a high-intensity energy source 430 from which a high-intensity energy beam 434 emanates to irradiate the untreated surface 454 of the roll of material 414 to smooth the untreated surface 454, such as shown in FIGS. 2A and 2B, producing a smoothed surface 458, such as shown in FIGS. 3A and 3B, on the substrate; in this way, the surface is smoothed to remove defects from the surface by creating the altered surface layer 304b. The high-intensity energy beam 434 may have a range 438 over which the high-intensity energy beam 434 irradiates the surface of the unwound portion of the roll of material 414. The range 438 may be provided by homogenizing the beam to produce a wide spot with a beam homogenizer, or by rastering a focused spot back and forth along the direction of transport as indicated by the double-headed arrow corresponding to the range 438. As the substrate also has a width, the high-intensity energy beam 434 may be rastered in the width direction, perpendicular to the direction of transport (not shown), to smooth the full surface of the substrate. As shown in FIG. 4, the untreated surface 454 is the outer surface of the roll of material 414. Alternatively, by disposing a treatment station on the opposite, or bottom, side of the unwound portion from that shown, the inner surface of the roll of material 414 may be smoothed (not shown).

With further reference to FIG. 4, in accordance with an embodiment of the present invention, after the surface has been smoothed, the altered surface layer is configured to receive at least one layer in a fabrication process of an electronic device, for example, as described above in FIG. 3B. In accordance with an embodiment of the present invention, the substrate may be selected from a group including a metallic substrate and a metallized substrate, for example, a metallized non-metallic substrate including a flexible, non-conductive substrate, such as a polymer substrate, with a sputtered metallic layer. In addition, the electronic device may include a solar cell having absorber layer 362 made of, for example, CIGS material. In accordance with an embodiment of the present invention, the high-intensity energy source may include a laser selected from a group consisting of a Q-switched laser, a Q-switched Nd:YAG laser, a Q-switched fiber laser, a Q-switched disc laser, a Q-switched slab laser, a carbon-dioxide laser, a pulsed laser, a continuous-wave laser, and a diode laser. Moreover, smoothing may include a laser smoothing including a process selected from a group including a laser ablation process, a laser melting-resolidification process, and a laser-induced, surface-alloying process.

With further reference to FIG. 4 in conjunction with FIG. 3B, in accordance with embodiments of the present invention, the roll-to-roll surface smoother 400 may be used in fabricating a solar cell. The solar cell may include a substrate 304, a surface of the substrate 304 smoothed by irradiating the surface with a high-intensity energy source 430, wherein the surface is smoothed to remove defects from the surface by creating an altered surface layer 304b; and an absorber layer 362 disposed on the altered surface layer 304b. The absorber layer 362 of the solar cell may further include copper indium gallium diselenide (CIGS). In further embodiments of the present invention, the substrate 304 of the solar cell may be selected from a group consisting of a metallic substrate and a metallized substrate. Moreover, the substrate 304 may have a width of about 1 m and a thickness of less than about 125 μm. In an embodiment of the present invention, the altered surface layer 304b of the solar cell has a thickness of less than about 25 μm.

### Description of Embodiments of the Present Invention for a Method of Smoothing a Metallic Substrate for a Solar Cell

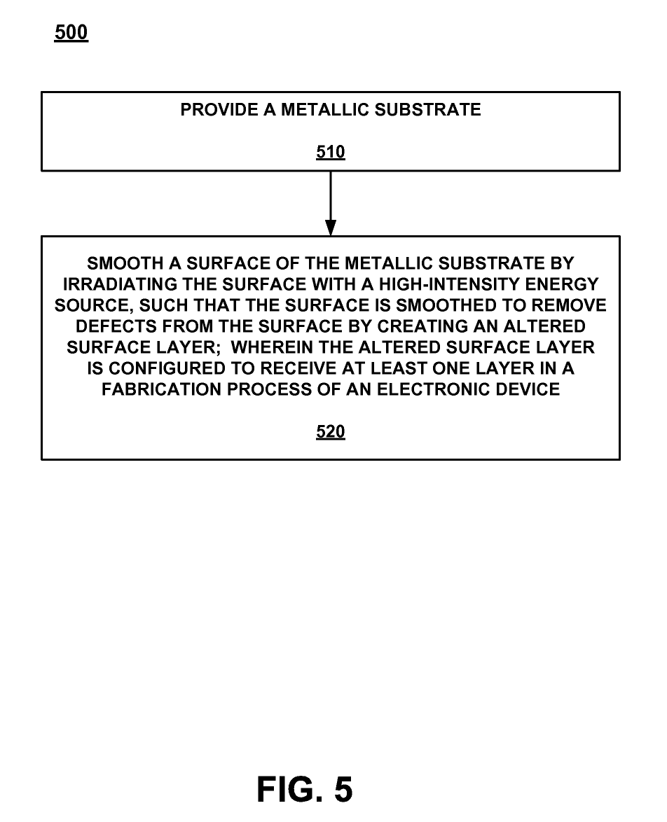

With reference now to FIG. 5, a flow chart illustrates an embodiment of the present invention for a method 500 for smoothing the surface of a metallic substrate. At 510, a metallic substrate is provided. At 520, a surface of the metallic substrate is smoothed by irradiating the surface with a high-intensity energy source, such that the surface is smoothed to remove defects from the surface by creating an altered surface layer, in which the altered surface layer is configured to receive at least one layer in a fabrication process of an electronic device. In one embodiment, the altered surface layer produced by the method has a thickness of less than about 5 μm; alternatively, the altered surface layer may have a thickness of less than about 25 μm depending on the power delivered to the surface by the high-intensity energy source. Also, an electronic device fabricated with the method may include a solar cell. In addition, at least one layer of an electronic device fabricated with the method may include CIGS.

With further reference to FIG. 5, it should be recognized that rough substrate surfaces can result in diode shunt sites that result in loss of output power from the solar cell, for example, as described above in FIGS. 2A and 2B. Laser smoothing by surface melting locally smoothes the surface by melting and reflowing the surface features without fully penetrating the substrate with the laser melt zone. Therefore, the smoothing includes a laser smoothing. The use of laser smoothing facilitates the fabrication of the solar cell by allowing the subsequent deposition of continuous and un-interrupted thin-film layers of solar-cell materials, for example, the absorber layer, on a smoothed metallic substrate. In an example laser-smoothing process, the laser preferentially heats regions of the surface having lesser heat capacity than the base portion of the metallic substrate, for example, regions with the topography of a protrusion or pit. In addition, such features can be removed by laser smoothing based on laser ablation. Therefore, the laser smoothing may also include a process selected from a group including a laser ablation process, a laser melting-resolidification process, and a laser-induced, surface-alloying process.

In accordance with an embodiment of the present invention, the latter process, laser-induced, surface-alloying, can be accomplished by a variety of methods, including without limitation: applying a material to the surface of the metallic substrate before or during the laser-smoothing process to form a thin-film barrier layer, for example, chromium, Cr, which blocks the out-diffusion of impurities, e.g. iron, Fe, or nickel, Ni, from the metallic substrate that may have a deleterious effect on solar-cell performance; or, exposing the surface to reactive gases such as nitrogen or oxygen during the laser-smoothing process to form a nitrided, or oxidized, thin-film layer, for example, a thin-film, surface nitride or oxide layer. In the alternative to exposing the surface to a reactive gas, the surface may be shrouded in an envelope of inert gas, for example, argon, Ar, during the laser-smoothing process to maintain surface cleanliness. Moreover, the application of material to the surface of the metallic substrate, before or during the laser-smoothing process, may also include depositing a surface-treatment layer on the metallic substrate. Thus, in accordance with an embodiment of the present invention, depositing a surface-treatment layer may also include a deposition process selected from a group including physical vapor deposition (PVD), chemical vapor deposition (CVD), sol-gel deposition, sputtering, sputtering in a reactive atmosphere, cladding, laser cladding, electroplating, and electroless plating. Also, in the case of laser cladding, the cladding material may be provided from a variety of sources, including without limitation: powder, wire, liquid, as well as others within the scope and spirit of embodiments of the present invention.

With further reference to FIG. 5, in accordance with an embodiment of the present invention, various laser scanning techniques can be employed to deliver energy from the laser to the surface of the metallic substrate. For example, in an embodiment of the present invention, a laser galvanometer scanner may be used to scan a laser beam across the surface of the metallic substrate; or alternatively, a linear laser source may be used to irradiate a line, rather than a spot, on the surface of the metallic substrate. Moreover, the high-intensity energy source may also include a laser selected from a group including a Q-switched laser, a Q-switched Nd:YAG laser, a Q-switched fiber laser, a Q-switched disc laser, a Q-switched slab laser, a carbon-dioxide laser, a pulsed laser, a continuous-wave laser, and a diode laser, as embodiments within the spirit and scope of embodiments of the present invention.

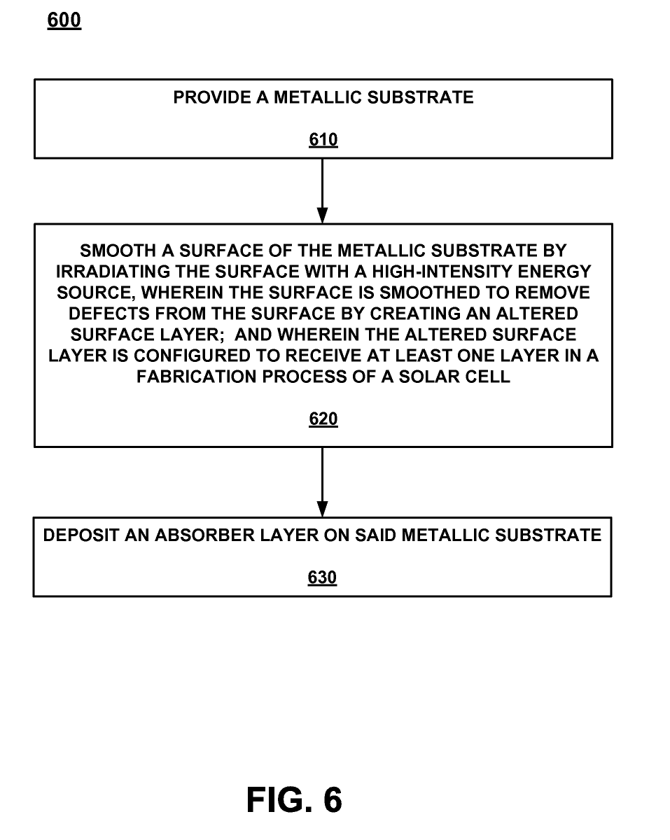

With reference now to FIG. 6, a flow chart illustrates an embodiment of the present invention for a method 600 for fabricating a solar cell. At 610, a metallic substrate is provided. At 620, a surface of the metallic substrate is smoothed by irradiating the surface with a high-intensity energy source, wherein the surface is smoothed to remove defects from the surface by creating an altered surface layer, and wherein the altered surface layer is configured to receive at least one layer in a fabrication process of a solar cell. At 630, an absorber layer is deposited on the metallic substrate. In one embodiment, the altered surface layer produced by the method has a thickness of less than about 5 μm; alternatively, the altered surface layer may have a thickness of less than about 25 μm depending on the power delivered to the surface by the high-intensity energy source. In an embodiment of the present invention, the absorber layer fabricated with the method includes CIGS.

With further reference to FIG. 6, in the embodiment of the present invention for the method 600, the smoothing further includes a laser smoothing. The laser smoothing further includes a process selected from a group including a laser ablation process, a laser melting-resolidification process, and a laser-induced, surface-alloying process. In addition, the high-intensity energy source of the method may also include a laser selected from a group including a Q-switched laser, a Q-switched Nd:YAG laser, a Q-switched fiber laser, a Q-switched disc laser, a Q-switched slab laser, a carbon-dioxide laser, a pulsed laser, a continuous-wave laser, and a diode laser, as embodiments within the spirit and scope of embodiments of the present invention.

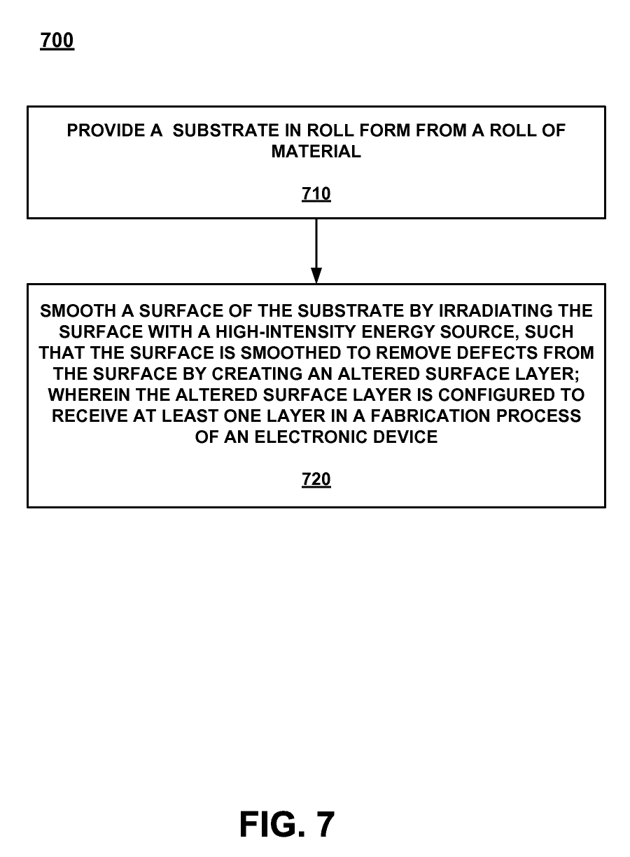

With reference now to FIG. 7, a flow chart illustrates an embodiment of the present invention for a method 700 for roll-to-roll smoothing the surface of a roll of material. At 710, a substrate in roll form from a roll of material is provided. At 720, a surface of the roll of material is smoothed by irradiating the surface with a high-intensity energy source, such that the surface is smoothed to remove defects from the surface by creating an altered surface layer, in which the altered surface layer is configured to receive at least one layer in a fabrication process of an electronic device. In an embodiment of the present invention, the substrate is selected from a group including a metallic substrate and a metallized substrate, for example, a metallized non-metallic substrate including a flexible, non-conductive substrate, such as a polymer substrate, with a sputtered metallic layer. In one embodiment, the altered surface layer produced by the method has a thickness of less than about 5 μm; alternatively, the altered surface layer may have a thickness of less than about 25 μm depending on the power delivered to the surface by the high-intensity energy source. Also, an electronic device fabricated with the method may include a solar cell. In addition, at least one layer of an electronic device fabricated with the method may include CIGS.

With further reference to FIG. 7, it should be recognized that rough substrate surfaces can result in diode shunt sites that result in loss of output power from the solar cell, for example, as described above in FIGS. 2A and 2B. Laser smoothing by surface melting locally smoothes the surface by melting and reflowing the surface features without fully penetrating the substrate with the laser melt zone. Therefore, the smoothing includes a laser smoothing. The use of laser smoothing facilitates the fabrication of the solar cell by allowing the subsequent deposition of continuous and un-interrupted thin-film layers of solar-cell materials, for example, the absorber layer, on a smoothed substrate. In an example laser-smoothing process, the laser preferentially heats regions of the surface having lesser heat capacity than the base portion of the substrate, for example, regions with the topography of a protrusion or pit. In addition, such features can be removed by laser smoothing based on laser ablation. Therefore, the laser smoothing may also include a process selected from a group including a laser ablation process, a laser melting-resolidification process, and a laser-induced, surface-alloying process.

In accordance with an embodiment of the present invention, the latter process, laser-induced, surface-alloying, can be accomplished by a variety of methods, including without limitation: applying a material to the surface of the substrate before or during the laser-smoothing process to form a thin-film barrier layer, for example, chromium, Cr, which blocks the out-diffusion of impurities, e.g. iron, Fe, or nickel, Ni, from the substrate that may have a deleterious effect on solar-cell performance; or, exposing the surface to reactive gases such as nitrogen or oxygen during the laser-smoothing process to form a nitrided, or oxidized, thin-film layer, for example, a thin-film, surface nitride or oxide layer. In the alternative to exposing the surface to a reactive gas, the surface may be shrouded in an envelope of inert gas, for example, argon, Ar, during the laser-smoothing process to maintain surface cleanliness. Moreover, the application of material to the surface of the substrate before or during the laser-smoothing process may also include depositing a surface-treatment layer on the substrate. Thus, in accordance with an embodiment of the present invention, depositing a surface-treatment layer may also include a deposition process selected from a group including physical vapor deposition (PVD), chemical vapor deposition (CVD), sol-gel deposition, sputtering, sputtering in a reactive atmosphere, cladding, laser cladding, electroplating, and electroless plating. Also, in the case of laser cladding, the cladding material may be provided from a variety of sources, including without limitation: powder, wire, liquid, as well as others within the scope and spirit of embodiments of the present invention.

With further reference to FIG. 7, in accordance with an embodiment of the present invention, various laser scanning techniques can be employed to deliver energy from the laser to the surface of the substrate. For example, in an embodiment of the present invention, a laser galvanometer scanner may be used to scan a laser beam across the surface of the substrate; or alternatively, a linear laser source may be used to irradiate a line, rather than a spot, on the surface of the substrate. Moreover, the high-intensity energy source may also include a laser selected from a group including a Q-switched laser, a Q-switched Nd:YAG laser, a Q-switched fiber laser, a Q-switched disc laser, a Q-switched slab laser, a carbon-dioxide laser, a pulsed laser, a continuous-wave laser, and a diode laser, as embodiments within the spirit and scope of embodiments of the present invention.

The foregoing descriptions of specific embodiments of the present invention have been presented for purposes of illustration and description. They are not intended to be exhaustive or to limit the invention to the precise forms disclosed, and many modifications and variations are possible in light of the above teaching. The embodiments described herein were chosen and described in order to best explain the principles of the invention and its practical application, to thereby enable others skilled in the art to best utilize the invention and various embodiments with various modifications as are suited to the particular use contemplated. It is intended that the scope of the invention be defined by the claims appended hereto and their equivalents.

What is claimed is:

1. A method for smoothing the surface of a metallic substrate, said method comprising:
providing a metallic substrate; and
smoothing a surface of said metallic substrate by irradiating said surface with a high-intensity energy source, such that said surface is smoothed to remove defects from said surface by creating an altered surface layer;
wherein said altered surface layer is configured to receive at least one layer in a fabrication process of an electronic device.

2. The method recited in claim 1, wherein said electronic device comprises a solar cell.

3. The method recited in claim 1, wherein said at least one layer comprises copper indium gallium diselenide (CIGS).

4. The method recited in claim 1, wherein said smoothing further comprises a laser smoothing.

5. The method recited in claim 4, wherein said laser smoothing further comprises a process selected from a group consisting of a laser ablation process, a laser melting-resolidification process, and a laser-induced, surface-alloying process.

6. The method recited in claim 1, further comprising:
depositing a surface-treatment layer on said metallic substrate.

7. The method recited in claim 1, wherein said high-intensity energy source further comprises a laser selected from a group consisting of a Q-switched laser, a Q-switched Nd:YAG laser, a Q-switched fiber laser, a Q-switched disc laser, a Q-switched slab laser, a carbon-dioxide laser, a pulsed laser, a contilluous-wave laser, and a diode laser.

8. A method for fabricating a solar cell, said method comprising:
providing a metallic substrate;
smoothing a surface of said metallic substrate by irradiating said surface with a high-intensity energy source, wherein said surface is smoothed to remove defects from said surface by creating an altered surface layer, and wherein said altered surface layer is configured to receive at least one layer in a fabrication process of a solar cell; and
depositing an absorber layer on said metallic substrate.

9. The method recited in claim 8, wherein said absorber layer further comprises copper indium gallium diselenide (CIGS).

10. The method recited in claim 8, wherein said smoothing further comprises a laser smoothing.

11. The method recited in claim 10, wherein said laser smoothing further comprises a process selected from a group consisting of a laser ablation process, a laser melting-resolidification process, and a laser-induced, surface-alloying process.

12. The method recited in claim 8, wherein said high-intensity energy source further comprises a laser selected from a group consisting of a Q-switched laser, a Q-switched Nd:YAG laser, a Q-switched fiber laser, a Q-switched disc laser, a Q-switched slab laser, carbon-dioxide laser, a pulsed laser, a continuous-wave laser, and a diode laser.

13. A solar cell, comprising:
a metallic substrate, a surface of said metallic substrate smoothed by irradiating said surface with a high-intensity energy source, wherein said surface is smoothed to remove defects from said surface by creating an altered surface layer; and,
an absorber layer disposed on said altered surface layer.

14. The solar cell of claim 13, wherein said absorber layer further comprises copper indium gallium diselenide (CIGS).

15. A method for roll-to-roll smoothing the surface of a substrate, said method comprising:
providing a substrate in roll form from a roll of material; and
smoothing a surface of said substrate by irradiating said surface with a high-intensity energy source, such that said surface is smoothed to remove defects from said surface by creating an altered surface layer;
wherein said altered surface layer is configured to receive at least one layer in a fabrication process of an electronic device.

16. The method recited in claim 15, wherein said substrate is selected from a group consisting of a metallic substrate and a metallized substrate.

17. The method recited in claim 16, wherein said electronic device comprises a solar cell.

18. The method recited in claim 15, wherein said smoothing further comprises a laser smoothing.

19. The method recited in claim 18, wherein said laser smoothing further comprises a process selected from a group consisting of a laser ablation process, a laser melting-resolidification process, and a laser-induced, surface-alloying process.

20. The method recited in claim 15, wherein said high-intensity energy source further comprises a laser selected from a group consisting of a Q-switched laser, a Q-switched Nd:YAG laser, a Q-switched fiber laser, a Q-switched disc laser, a Q-switched slab laser, a carbon-dioxide laser, a pulsed laser, a continuous-wave laser, and a diode laser.

21. A solar cell, comprising:
a substrate, a surface of said substrate smoothed by irradiating said surface with a high-intensity energy source, wherein said surface is smoothed to remove defects from said surface by creating an altered surface layer; and,
an absorber layer disposed on said altered surface layer.

22. The solar cell of claim 21, wherein said absorber layer further comprises copper indium gallium diselenide (CIGS).

23. The solar cell of claim 21, wherein said substrate is selected from a group consisting of a metallic substrate and a metallized substrate.

24. The solar cell of claim 21, wherein said substrate has a width of about 1 m and a thickness of less than about 125 μm.

25. The solar cell of claim 21, wherein said altered surface layer has a thickness of less than about 25 μM.
